(19) United States
(12) Patent Application Publication
(10) Pub. No.: US 2024/0395917 A1
(43) Pub. Date: Nov. 28, 2024

(54) INSULATED GATE BIPOLAR TRANSISTOR AND MANUFACTURING METHOD THEREOF, ELECTRONIC APPARATUS, AND STORAGE MEDIUM

(71) Applicants: EDGELESS SEMICONDUCTOR CO., LTD. OF ZHUHAI, Zhuhai (CN); GREE ELECTRIC APPLIANCES, INC. OF ZHUHAI, Zhuhai (CN)

(72) Inventors: Chunyan LI, Zhuhai (CN); Xiaohao GE, Zhuhai (CN); Dan ZENG, Zhuhai (CN)

(73) Assignees: EDGELESS SEMICONDUCTOR CO., LTD. OF ZHUHAI, Zhuhai (CN); GREE ELECTRIC APPLIANCES, INC. OF ZHUHAI, Zhuhai (CN)

(21) Appl. No.: 18/795,617

(22) Filed: Aug. 6, 2024

Related U.S. Application Data
(63) Continuation of application No. PCT/CN2022/140388, filed on Dec. 20, 2022.

(30) Foreign Application Priority Data
Feb. 21, 2022 (CN) 202210156399.7

(51) Int. Cl. H01L 29/739; H01L 21/311; H01L 29/10; H01L 29/16; H01L 29/40; H01L 29/66

(52) U.S. Cl. CPC H01L 29/7397; H01L 21/31111; H01L 29/1095; H01L 29/16; H01L 29/401; H01L 29/66348

(57) ABSTRACT

Disclosed are an insulated gate bipolar transistor and a manufacturing method thereof, an electronic apparatus, and a storage medium. In the insulated gate bipolar transistor manufactured by the method for manufacturing the insulated gate bipolar transistor, a structure sequentially includes a second metal layer, an oxide layer, an epitaxial layer and a first metal layer, a manufacturing process is simple, and the insulated gate bipolar transistor is manufactured into a vertical structure, which not only can reduce a leakage current of an insulated gate bipolar transistor, improving reliability of an insulated gate bipolar transistor, but also solves a problem of an insufficient withstand voltage of a lateral insulated gate bipolar transistor, improving user experience.

### CROSS-REFERENCE TO RELATED APPLICATIONS

The present disclosure is a continuation of International Application No. PCT/CN2022/140388, filed on Dec. 20, 2022, which claims priority to Chinese Patent Application No. 202210156399.7, filed on Feb. 21, 2022. The disclosures of the aforementioned applications are hereby incorporated by reference in their entireties.

### TECHNICAL FIELD

The present disclosure relates to the field of semiconductor devices, and in particular, to an insulated gate bipolar transistor and a manufacturing method thereof, an electronic apparatus, and a storage medium.

### BACKGROUND

With development of modern energy technologies, at present, electric energy has become one of the most main forms of energy. In processes of generation, transmission and use of electric energy, parameters such as a voltage, a current and a frequency are all needed to be adjusted, and these adjustment processes all depend on development of a power electronics technology. With the development of the power electronics technology, applications of various frequency conversion circuits and chopper circuits are constantly expanding. In these circuits, various power semiconductor devices are widely used, among which an IGBT (Insulated Gate Bipolar Transistor) is a commonly used power semiconductor device.

At present, the manufacturing of an IGBT is relatively simple, however, a withstand voltage of a manufactured IGBT is relatively low. As operating temperature of an IGBT device continues to rise, a leakage current of the IGBT device may be increased, resulting in poor reliability of an IGBT. Therefore, how to improve reliability of a structure of an IGBT has become an urgent problem to be solved.

### SUMMARY

The present disclosure provides an insulated gate bipolar transistor and a manufacturing method thereof, an electronic apparatus, and a storage medium, to solve a problem of poor reliability of an insulated gate bipolar transistor in related technologies.

In a first aspect, the present disclosure provides a method for manufacturing an insulated gate bipolar transistor, including: providing a substrate, and sequentially disposing an oxide layer and an epitaxial layer on the substrate, the epitaxial layer including a first epitaxial layer, a second epitaxial layer and a third epitaxial layer that are sequentially disposed; disposing a trench at a side, away from the oxide layer, of the third epitaxial layer, and disposing a polysilicon gate in the trench; forming, by injecting a dopant with a first charge type into the side, away from the oxide layer, of the third epitaxial layer, a body region disposed at two sides of the polysilicon gate; forming, by injecting a dopant with a second charge type into a side, away from the epitaxial layer, of the body region, an emitting region disposed at two side of the polysilicon gate; disposing a first metal layer covering the polysilicon gate, the emitting region and the body region; removing the substrate, and etching the oxide layer and the first epitaxial layer, to dispose through holes spaced apart from each other on the oxide layer and the first epitaxial layer, respectively; and disposing a second metal layer at a side, away from the epitaxial layer, of the oxide layer, the second metal layer being in contact with the second epitaxial layer through the through holes on the oxide layer and the first epitaxial layer.

In some embodiments, the disposing a trench at a side, away from the oxide layer, of the third epitaxial layer, and disposing a polysilicon gate in the trench includes: disposing an initial oxide layer on the third epitaxial layer, and coating glue on the initial oxide layer; etching the initial oxide layer after the initial oxide layer coated with the glue is exposed and developed; etching the third epitaxial layer after the initial oxide layer is etched, to form the trench on the third epitaxial layer; removing the initial oxide layer, and growing a gate oxide layer in the trench, to obtain the gate oxide layer; and disposing polysilicon on the gate oxide layer, to form the polysilicon gate.

In some embodiments, before the disposing a first metal layer covering the polysilicon gate, the emitting region and the body region, the method further includes: depositing a dielectric oxide layer on the polysilicon gate and the emitting region; and etching the dielectric oxide layer, to form a dielectric layer covering the polysilicon gate and a portion of the emitting region.

In some embodiments, the disposing a first metal layer covering the polysilicon gate, the emitting region and the body region includes: depositing a metal layer on the dielectric layer, the emitting region and the body region; coating glue on the metal layer, and then performing exposure and development on the metal layer coated with the glue; and etching the metal layer, to form the first metal layer.

In some embodiments, the disposing a second metal layer at a side, away from the epitaxial layer, of the oxide layer includes: depositing a metal layer on the oxide layer, coating glue on the metal layer, and then performing exposure and development on the metal layer coated with the glue; and etching the metal layer, to form the second metal layer, so that the second metal layer is in contact with the second epitaxial layer through the through holes on the oxide layer and the first epitaxial layer.

In some embodiments, the dopant with the first charge type and the dopant with the second charge type are dopants with different charge types; and the dopant with the first charge type is a B-ion dopant, and the dopant with the second charge type is an As-ion dopant.

In some embodiments, a material of the substrate is silicon.

In a second aspect, the present disclosure provides an insulated gate bipolar transistor, including: an oxide layer disposed with through holes; an epitaxial layer disposed at a side of the oxide layer, the epitaxial layer including a first epitaxial layer, a second epitaxial layer and a third epitaxial layer that are sequentially disposed, and the first epitaxial layer being disposed with through holes; a trench disposed at a side, away from the oxide layer, of the third epitaxial layer, a polysilicon gate being disposed in the trench; a body region disposed at the side, away from the oxide layer, of the third epitaxial layer, and further disposed at two sides of the polysilicon gate; an emitting region disposed at a side, away from the epitaxial layer, of the body region, and further disposed at two sides of the polysilicon gate; a first metal layer disposed at sides, away from the epitaxial layer, of the body region and the emitting region; and a second metal layer disposed at a side, away from the epitaxial layer, of the oxide layer, the second metal layer being in contact with the second epitaxial layer through the through holes on the oxide layer and the first epitaxial layer.

In a third aspect, the present disclosure provides an electronic apparatus, including a processor, a communication interface, a memory and a communication bus, and the processor, the communication interface and the memory communicate with each other via the communication bus; the memory is set to store a computer program; and the processor is set to implement the steps of the method for manufacturing the insulated gate bipolar transistor according to any one of the above-mentioned embodiments in the first aspect, when executing the computer program stored in the memory.

In a fourth aspect, the present disclosure provides a non-transitory computer-readable storage medium, on which a computer program is stored, and when the computer program is executed by a processor, the steps of the method for manufacturing the insulated gate bipolar transistor according to any one of the above-mentioned embodiments in the first aspect are implemented.

Compared with the related technologies, the above-mentioned technical solutions according to the embodiments of the present disclosure have advantages as follows.

The method provided by the embodiments of the present disclosure includes: providing a substrate, and sequentially disposing an oxide layer and an epitaxial layer on the substrate, the epitaxial layer including a first epitaxial layer, a second epitaxial layer and a third epitaxial layer that are sequentially disposed; disposing a trench at a side, away from the oxide layer, of the third epitaxial layer, and disposing a polysilicon gate in the trench; forming, by injecting a dopant with a first charge type into the side, away from the oxide layer, of the third epitaxial layer, a body region disposed at two sides of the polysilicon gate; forming, by injecting a dopant with a second charge type into a side, away from the epitaxial layer, of the body region, an emitting region disposed at two side of the polysilicon gate; disposing a first metal layer covering the polysilicon gate, the emitting region and the body region; removing the substrate, and etching the oxide layer and the first epitaxial layer, to dispose through holes spaced apart from each other on the oxide layer and the first epitaxial layer, respectively; and disposing a second metal layer at a side, away from the epitaxial layer, of the oxide layer, the second metal layer being in contact with the second epitaxial layer through the through holes on the oxide layer and the first epitaxial layer. As for the insulated gate bipolar transistor manufactured by the method for manufacturing the insulated gate bipolar transistor mentioned above, a structure includes a second metal layer, an oxide layer, an epitaxial layer and a first metal layer, a manufacturing process is simple, and the insulated gate bipolar transistor is manufactured into a vertical structure, which not only can reduce a leakage current of an insulated gate bipolar transistor, improving reliability of an insulated gate bipolar transistor, but also solves a problem of an insufficient withstand voltage of a lateral insulated gate bipolar transistor, improving user experience.

### BRIEF DESCRIPTION OF THE DRAWINGS

The accompanying drawings herein are incorporated into the specification and constitute a portion of the specification. The accompanying drawings illustrate embodiments consistent with the present disclosure, and are used together with the specification to explain principles of the present disclosure.

In order to more clearly explain technical solutions of embodiments of the present disclosure or the related technologies, the accompanying drawings needed in description of the embodiments or the related technologies may be briefly introduced below. Apparently, as for a person with ordinary skill in the art, other accompanying drawings may be obtained according to these accompanying drawings without paying creative labor.

FIG. 1 is a schematic diagram of a flowchart of a method for manufacturing an insulated gate bipolar transistor according to an embodiment of the present disclosure.

FIG. 2 is a schematic basic structural diagram of an oxide layer and an epitaxial layer according to an embodiment of the present disclosure.

FIG. 3 is a schematic basic structural diagram of a gate oxide layer according to an embodiment of the present disclosure.

FIG. 4 is a schematic basic structural diagram of a polysilicon gate according to an embodiment of the present disclosure.

FIG. 5 is a schematic basic structural diagram of a dielectric oxide layer according to an embodiment of the present disclosure.

FIG. 6 is a schematic basic structural diagram of a dielectric layer according to an embodiment of the present disclosure.

FIG. 7 is a schematic basic structural diagram of a first metal layer according to an embodiment of the present disclosure.

FIG. 8 is a schematic basic structural diagram of an oxide layer disposing with through holes according to an embodiment of the present disclosure.

FIG. 9 is a schematic basic structural diagram of a second metal layer according to an embodiment of the present disclosure.

FIG. 10 is a schematic structural diagram of an electronic apparatus according to an embodiment of the present disclosure.

### DETAILED DESCRIPTION OF THE EMBODIMENTS

In order to make purposes, technical solutions and advantages of the embodiments of the present disclosure clearer, the technical solutions in the embodiments of the present disclosure may be described clearly and completely with reference to the accompanying drawings in the embodiments of the present disclosure. Apparently, the described embodiments are a portion of the embodiments of the present disclosure, but not all the embodiments. Based on the embodiments in the present disclosure, all other embodiments obtained by a person with ordinary skill in the art without creative labor fall within the scope of protection of the present disclosure.

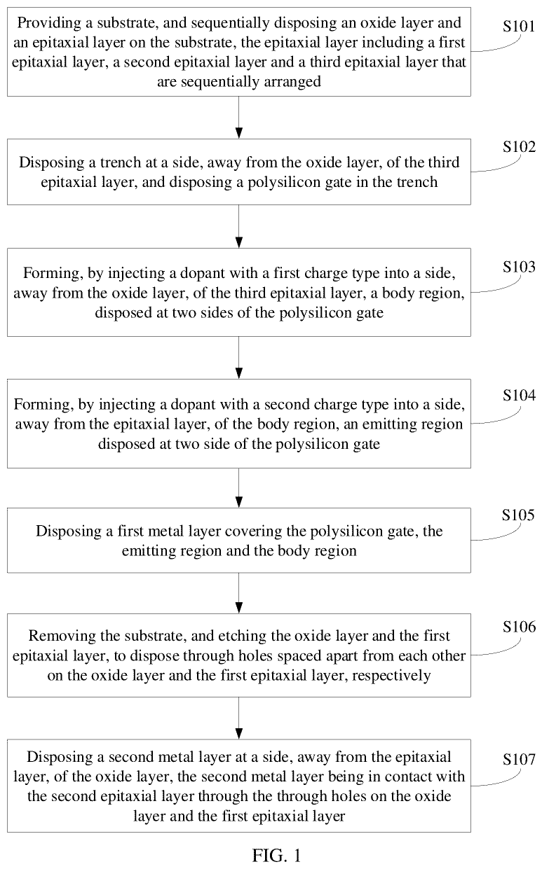

FIG. 1 is a schematic diagram of a flowchart of a method for manufacturing an insulated gate bipolar transistor according to an embodiment of the present disclosure. As shown in FIG. 1, the method for manufacturing the insulated gate bipolar transistor includes:

S101, providing a substrate, and sequentially disposing an oxide layer and an epitaxial layer on the substrate, the epitaxial layer including a first epitaxial layer, a second epitaxial layer and a third epitaxial layer that are sequentially arranged;

S102, disposing s trench at a side, away from the oxide layer, of the third epitaxial layer, and disposing a polysilicon gate in the trench;

S103, forming, by injecting a dopant with a first charge type into the side, away from the oxide layer, of the third epitaxial layer, a body region disposed at two sides of the polysilicon gate, the body region being a P-body region;

S104, forming, by injecting a dopant with a second charge type into a side, away from the epitaxial layer, of the body region, an emitting region disposed at the two side of the polysilicon gate;

S105, disposing a first metal layer covering the polysilicon gate, the emitting region and the body region;

S106, removing the substrate, and etching the oxide layer and the first epitaxial layer, to dispose through holes spaced apart from each other on the oxide layer and the first epitaxial layer, respectively; and

S107, disposing a second metal layer at a side, away from the epitaxial layer, of the oxide layer, the second metal layer being in contact with the second epitaxial layer through the through holes on the oxide layer and the first epitaxial layer.

It should be understood that, the epitaxial layer includes but is not limited to: the first epitaxial layer, the second epitaxial layer and the third epitaxial layer. I.e., the oxide layer, the first epitaxial layer, the second epitaxial layer and the third epitaxial layer are sequentially disposed on the substrate, the first oxide layer is a layer closest to the substrate, and the third epitaxial layer is a layer farthest away from the substrate. In some examples, the first epitaxial layer is a P+-type epitaxial layer, the second epitaxial layer is an N+-type epitaxial layer, and the third epitaxial layer is an N−-type epitaxial layer. It may be understood that, materials of the P+-type epitaxial layer, the N+-type epitaxial layer and the N−-type epitaxial layer can be flexibly set by a person skilled in the art, which are not described herein. Doping concentrations of the P+-type epitaxial layer and the N+-type epitaxial layer are both greater than a doping concentration of the N−-type epitaxial layer.

It may be understood that, a purpose of disposing the oxide layer is to increase a field turn-on voltage, so that the field turn-on voltage is greater than a working voltage, to form good isolation; and meanwhile, a purpose of disposing the oxide layer is also to reduce a parasitic capacitance between a silicon substrate and one of a metal layer and polysilicon.

In some examples of this embodiment, the disposing a trench at a side, away from the oxide layer, of the third epitaxial layer, and disposing a polysilicon gate in the trench includes: disposing an initial oxide layer on the third epitaxial layer, and coating glue on the initial oxide layer; etching the initial oxide layer after the initial oxide layer coated with the glue is exposed and developed; etching the third epitaxial layer after the initial oxide layer is etched, to form the trench on the third epitaxial layer; removing the initial oxide layer, and growing a gate oxide layer in the trench, to obtain the gate oxide layer; and disposing polysilicon on the gate oxide layer, to form the polysilicon gate. The trench is disposed at the side, away from the oxide layer, of the epitaxial layer, i.e., the trench is disposed on the third epitaxial layer. The initial oxide layer is disposed on the epitaxial layer, i.e., the initial oxide layer is disposed at a side, away from the substrate, of the epitaxial layer, i.e., an epitaxial layer is disposed on the third epitaxial layer.

Following the above examples, the initial oxide layer is disposed on the third epitaxial layer, the glue is coated on the initial oxide layer, the initial oxide layer coated with the glue is exposed and developed by using a Trench photomask, and then the initial oxide layer is etched. After the initial oxide layer is etched, the third epitaxial layer is etched to form the trench. After the trench is formed, the initial oxide layer is removed. After the initial oxide layer is removed, the gate oxide layer is grown in the trench, to obtain the gate oxide layer. It should be understood that, a method for disposing the initial oxide layer on the third epitaxial layer includes but is not limited to deposition or precipitation.

It may be understood that, after the initial oxide layer is disposed, the polysilicon may also be directly deposited in the trench, glue is coated on the polysilicon, the polysilicon coated with the glue is exposed and developed by using a Poly photomask, and then the polysilicon is etched, to form the polysilicon gate.

The body region is formed by injecting the dopant with the first charge type into the side, away from the oxide layer, of the epitaxial layer, and the body region is disposed at the two sides of the polysilicon gate. The emitting region is formed by injecting the dopant with the second charge type into the side, away from the epitaxial layer, of the body region, and the emitting region is disposed at the two side of the polysilicon gate. It may be understood that, after etching of the polysilicon is completed to form the polysilicon gate, the dopant with the first charge type is injected into the side, away from the oxide layer, of the third epitaxial layer, to form the body region, and then the dopant with the second charge type is injected into the side, away from the epitaxial layer, of the body region, to form the N+-type emitting region. It should be understood that, in some examples, all regions, except for a region where the polysilicon gate is located, of the third epitaxial layer are covered by the body region, and the emitting region is embedded in the body region.

In some examples of this embodiment, before the disposing a first metal layer covering the polysilicon gate, the emitting region and the body region, the method further includes: depositing a dielectric oxide layer on the polysilicon gate and the emitting region; and etching the dielectric oxide layer, to form a dielectric layer covering the polysilicon gate and a portion of the emitting region. It should be understood that, the polysilicon gate is completely covered by the dielectric layer, and an area of the emitting region covered by the dielectric layer may be flexibly set by related personnels.

It should be understood that, after the dielectric oxide layer is deposited on the polysilicon gate and the emitting region, glue is coated on the dielectric oxide layer, the dielectric oxide layer coated with the glue is exposed and developed by using a Contact photomask, and then the dielectric oxide layer is etched, to further obtain the dielectric layer. A method for etching the dielectric oxide layer is not limited by this embodiment, such as dry etching or wet etching, and a specific etching method may be flexibly set by related personnels.

In some examples of this embodiment, the disposing a first metal layer covering the polysilicon gate, the emitting region and the body region includes: depositing a metal layer on the dielectric layer, the emitting region and the body region; coating glue on the metal layer, and then performing exposure and development on the metal layer coated with the glue; and etching the metal layer, to form the first metal layer.

It should be understood that, the metal layer is deposited on the dielectric layer, the emitting region and the body region, the glue is coated on the metal layer, the metal layer coated with the glue is exposed and developed by using a Metal photomask, and then the metal layer is etched, to further form the first metal layer.

In some examples of this embodiment, the disposing a second metal layer at a side, away from the epitaxial layer, of the oxide layer includes: depositing a metal layer on the oxide layer, coating glue on the metal layer, and then performing exposure and development on the metal layer coated with the glue; and etching the metal layer, to form the second metal layer, so that the second metal layer is in contact with the second epitaxial layer through the through holes on the oxide layer and the first epitaxial layer.

In some examples of this embodiment, the substrate is thinned to a backside, close to the substrate, of the oxide layer, glue is coated on the oxide layer, and the oxide layer coated with the glue is exposed and developed by using a backside photomask, and then the oxide layer and the first epitaxial layer are etched, so that there are a plurality of through holes spaced apart from each other on the oxide layer and the first epitaxial layer, respectively, and positions of the through holes on the oxide layer correspond to positions of the through holes on the first epitaxial layer, respectively, and a through hole on the oxide layer and a through hole on the first epitaxial layer of which position corresponds to that of the through hole on the oxide layer are interconnected with each other. Then metal is deposited on the oxide layer, and then the deposited metal is etched, to form the second metal layer, the second metal layer is in contact with the second epitaxial layer through the through holes on the oxide layer and the first epitaxial layer. It should be understood that, in some examples, a position of a protrusion of the second metal layer coincides with a position of a through hole on the first epitaxial layer, and therefore, the protrusion of the second metal layer is in contact with the first epitaxial layer.

In some examples of this embodiment, the dopant with the first charge type and the dopant with the second charge type are dopants with different charge types; and the dopant with the first charge type is a B-ion dopant, and the dopant with the second charge type is an As-ion dopant. Specific materials of the dopant with the first charge type and the dopant with the second charge type are not limited by this embodiment. Under a condition that in accordance with the concept of the present disclosure, the specific materials of the dopant with the first charge type and the dopant with the second charge type are flexibly set by related personnels.

In some examples of this embodiment, a material of the substrate is silicon. It should be understood that, the substrate may also be prepared using the following methods: EPI (Epitaxial) or FZ (Float Zone), i.e., the substrate may be an EPI substrate or an FZ substrate.

The method for manufacturing the insulated gate bipolar transistor provided by this embodiment includes: providing a substrate, and sequentially disposing an oxide layer and an epitaxial layer on the substrate, the epitaxial layer including a first epitaxial layer, a second epitaxial layer and a third epitaxial layer that are sequentially disposed; disposing a trench at a side, away from the oxide layer, of the third epitaxial layer, and disposing a polysilicon gate in the trench; forming, by injecting a dopant with a first charge type into the side, away from the oxide layer, of the third epitaxial layer, a body region disposed at two sides of the polysilicon gate; forming, by injecting a dopant with a second charge type into a side, away from the epitaxial layer, of the body region, an emitting region disposed at two side of the polysilicon gate; disposing a first metal layer covering the polysilicon gate, the emitting region and the body region; removing the substrate, and etching the oxide layer and the first epitaxial layer, to dispose through holes spaced apart from each other on the oxide layer and the first epitaxial layer, respectively; and disposing a second metal layer at a side, away from the epitaxial layer, of the oxide layer, the second metal layer being in contact with the second epitaxial layer through the through holes on the oxide layer and the first epitaxial layer. As for the insulated gate bipolar transistor manufactured by the method for manufacturing the insulated gate bipolar transistor mentioned above, a structure includes a second metal layer, an oxide layer, an epitaxial layer and a first metal layer, a manufacturing process is simple, and the insulated gate bipolar transistor is manufactured into a vertical structure, which not only helps to reduce a leakage current of an insulated gate bipolar transistor, improving reliability of an insulated gate bipolar transistor, but also solves a problem of an insufficient withstand voltage of a lateral insulated gate bipolar transistor, improving user experience.

In order to better understand the present disclosure, this embodiment provides a more specific example to explain the present disclosure. The example provides a method for manufacturing an insulated gate bipolar transistor, which includes but is not limited to the following content.

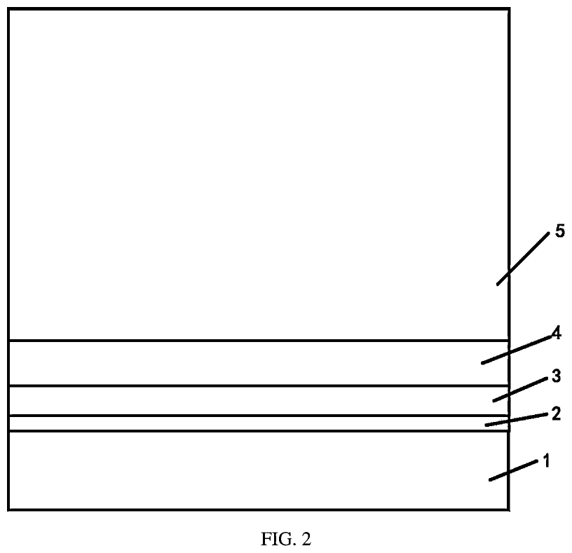

A substrate 1 is provided. The substrate 1 is a SOI (Silicon on Insulator) wafer, and an oxide layer 2 and an epitaxial layer are sequentially disposed on the substrate 1, shown in FIG. 2. The epitaxial layer includes but is not limited to: a first epitaxial layer 3, a second epitaxial layer 4 and a third epitaxial layer 5, i.e., the oxide layer 2, the first epitaxial layer 3, the second epitaxial layer 4 and the third epitaxial layer 5 are sequentially disposed on the substrate 1, the oxide layer 2 is a layer closest to the substrate 1, and the third epitaxial layer 5 is a layer farthest away from the substrate 1. In some examples, the first epitaxial layer 3 is a P+-type epitaxial layer, the second epitaxial layer 4 is an N+-type epitaxial layer, and the third epitaxial layer 5 is an N-type epitaxial layer. It may be understood that, materials of the P+-type epitaxial layer, the N+-type epitaxial layer and the N−-type epitaxial layer can be flexibly set by a person skilled in the art, which are not described herein. Doping concentrations of the P+-type epitaxial layer and the N+-type epitaxial layer are both greater than a doping concentration of the N−-type epitaxial layer.

A terminal region is manufactured. During a process of manufacturing the terminal region, there is no involvement of structural changes in a Cell region.

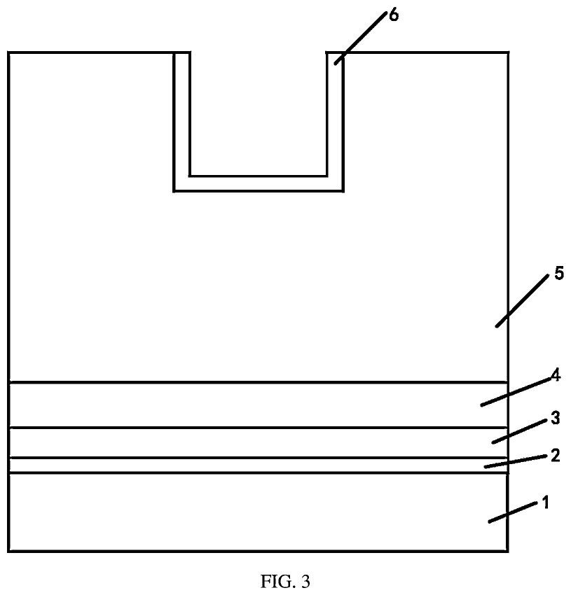

Etching is performed to form a trench, and a gate oxide layer 6 is grown in the trench. Specifically, an initial oxide layer is deposited on the third epitaxial layer 5, glue is coated on the initial oxide layer, the initial oxide layer coated with the glue is exposed and developed by using a Trench photomask, the initial oxide layer is etched, and then the third epitaxial layer 5 is etched, to form the trench. After the third epitaxial layer 5 is etched, the initial oxide layer is removed. After the initial oxide layer is removed, the gate oxide layer 6 is grown in the trench, to obtain the gate oxide layer 6, shown in FIG. 3.

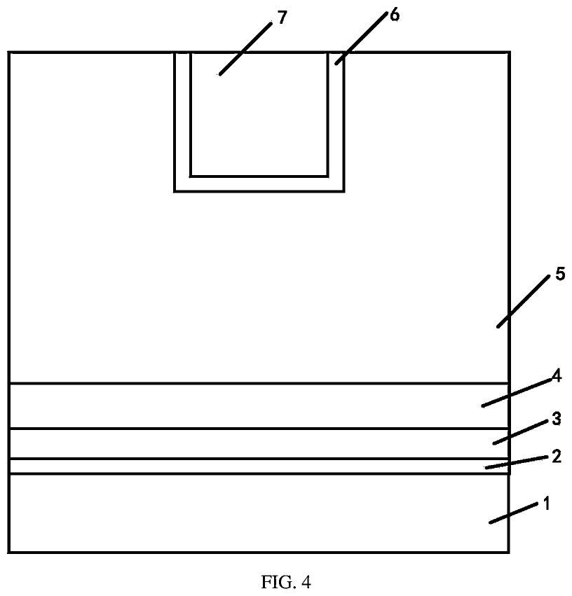

A polysilicon gate 7 is manufactured. Specifically, polysilicon is deposited on the gate oxide layer 6, glue is coated on the polysilicon, the polysilicon coated with the glue is exposed and developed by using a Poly photomask, and then the polysilicon is etched, to obtain the polysilicon gate 7, shown in FIG. 4.

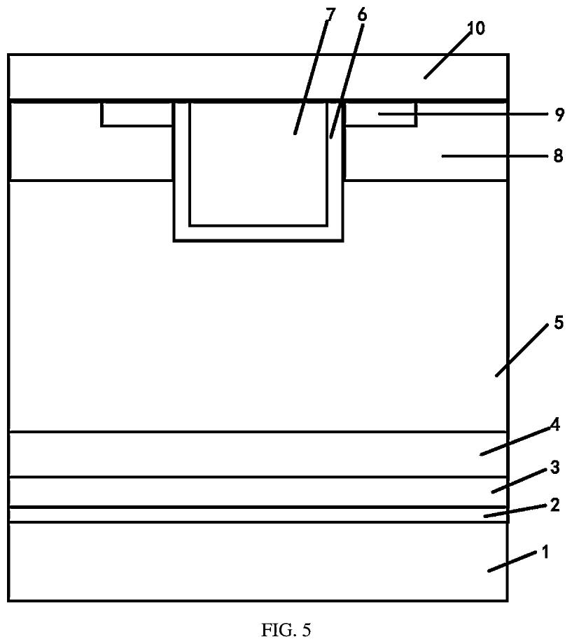

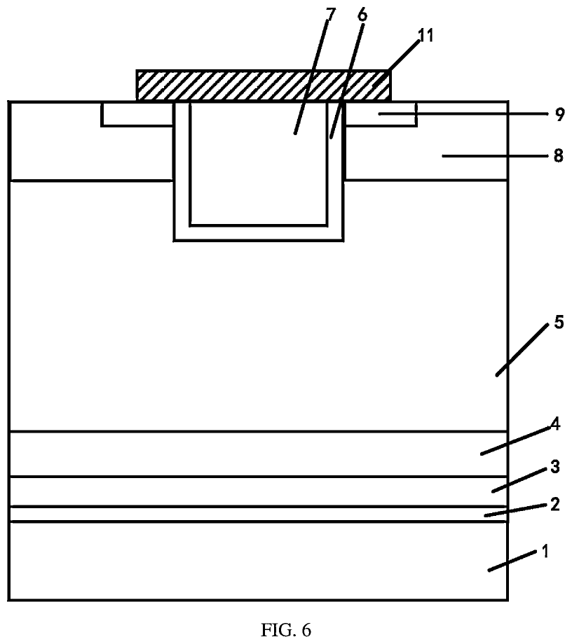

A body region 8, an N+-type emitting region 9 and a dielectric layer 11 are manufactured. Specifically, after etching of the polysilicon is completed to obtain the polysilicon gate 7, a B-ion is injected into a side, away from the oxide layer 2, of the third epitaxial layer 5, to form the body region 8; a doped boron-ion is injected into a silicon crystal, and then an As-ion is injected into a side, away from the epitaxial layer, of the body region 8, to form the N+-type emitting region 9; and a dielectric oxide layer 10 is deposited on the polysilicon gate 7 and the N+-type emitting region 9, shown in FIG. 5, and then the dielectric oxide layer 10 is etched, to form the dielectric layer 11, shown in FIG. 6, for example, glue is coated on the dielectric oxide layer 10, the dielectric oxide layer 10 coated with the glue is exposed and developed by using a Contact photomask, and then the dielectric oxide layer 10 is etched, to form the dielectric layer 11.

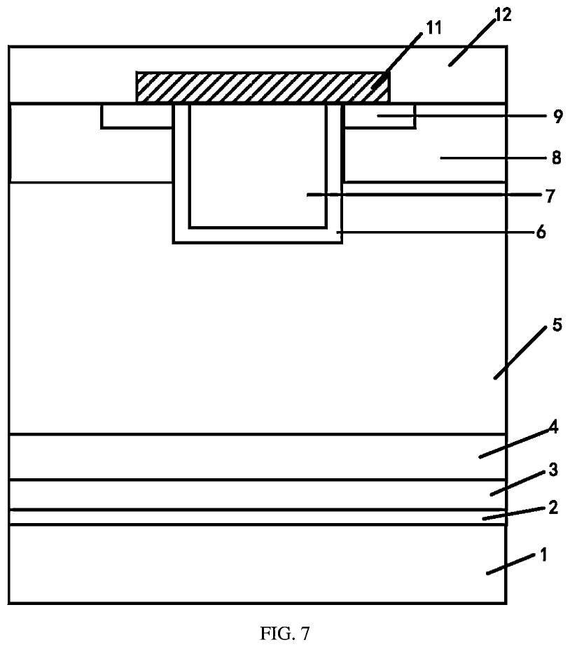

A contact hole and a metal layer at a frontside are manufactured. Specifically, a metal layer is deposited on the dielectric layer 11, the N+-type emitting region 9 and the body region 8, glue is coated on the metal layer, the metal layer coated with the glue is exposed and developed by using a Metal photomask, and then the metal layer is etched, to form the first metal layer 12, which serves as a metal electrode, for example, as an emitter, shown in FIG. 7.

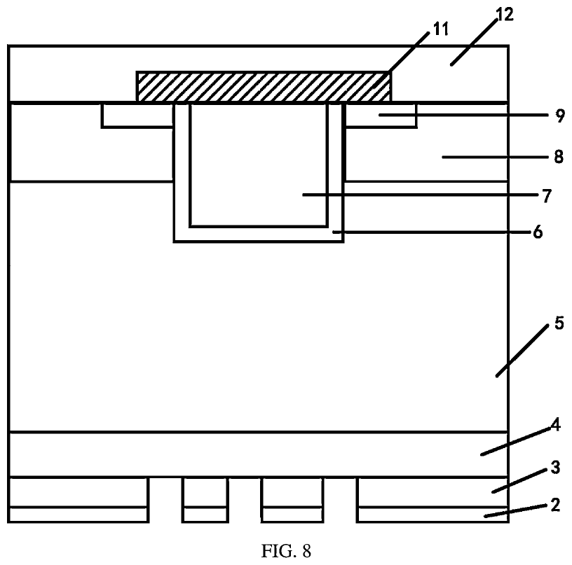

Thinning and etching are performed at a backside. Specifically, a backside of the wafer is thinned to a backside, close to the substrate 1, of the oxide layer 2, glue is coated on the oxide layer 2, the oxide layer 2 coated with the glue is exposed and developed by using a backside photomask, and then the oxide layer 2 and the first epitaxial layer 3 are etched, so that there are a plurality of through holes spaced apart from each other on the oxide layer 2 and the first epitaxial layer 3, respectively, shown in FIG. 8.

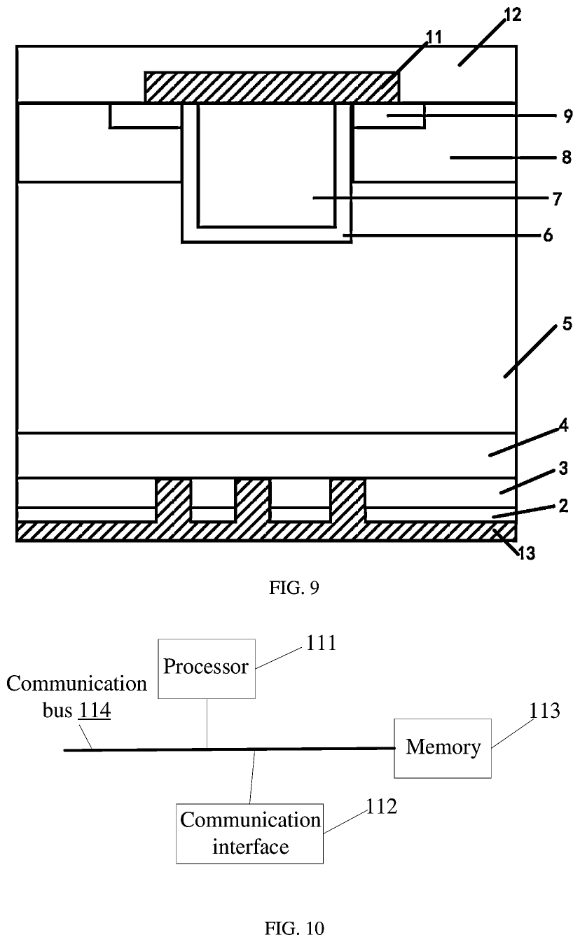

Metal is deposited on a backside. The metal is deposited on the backside, close to the substrate 1, of the oxide layer 2, to form a second metal layer 13, which serves as a metal electrode, for example, as a collector. The second metal layer 13 is in contact with the second epitaxial layer 4 through the through holes on the oxide layer 2 and the first epitaxial layer 3, shown in FIG. 9.

In the method for manufacturing the insulated gate bipolar transistor provided in this embodiment, a structure of the insulated gate bipolar transistor obtained before the second metal layer 13 is manufactured includes the substrate 1+the oxide layer 2+the P-type heavily doped epitaxial layer (i.e., the first epitaxial layer 3)+N-type heavily doped epitaxial layer (i.e., the second epitaxial layer 4)+N-type lightly doped epitaxial layer (i.e., the third epitaxial layer 5), and the manufacturing process is simple. When the second metal layer 13 is manufactured in a backside process, only one photolithography and one etching are required. A backside structure is designed by using a backside photolithography process and the design of a photomask, so that an IGBT with a vertical structure and based on the SOI substrate 1 may be successfully manufactured.

Based on the same concept, this embodiment provides an insulated gate bipolar transistor. As shown in FIG. 9, the insulated gate bipolar transistor includes:
an oxide layer 2 disposed with through holes;
an epitaxial layer disposed at a side of the oxide layer 2, the epitaxial layer including a first epitaxial layer 3, a second epitaxial layer 4 and a third epitaxial layer 5 that are sequentially disposed, and the first epitaxial layer 3 being disposed with through holes;
a trench disposed at a side, away from the oxide layer 2, of the third epitaxial layer 5, a polysilicon gate 7 being disposed in the trench;
a body region 8 disposed at the side, away from the oxide layer 2, of the third epitaxial layer 5, and further disposed at two sides of the polysilicon gate 7;
an emitting region 9 disposed at a side, away from the epitaxial layer, of the body region 8, and further disposed at two sides of the polysilicon gate 7;
a first metal layer 12 disposed at sides, away from the epitaxial layer, of the body region 8 and the emitting region 9; and
a second metal layer 13 disposed at a side, away from the epitaxial layer, of the oxide layer 2, the second metal layer 13 being in contact with the second epitaxial layer 4 through the through holes on the oxide layer 2 and the first epitaxial layer 3.

It should be understood that, the insulated gate bipolar transistor provided in this embodiment is manufactured by the method for manufacturing the insulated gate bipolar transistor provided in the above-mentioned embodiments. Therefore, as for the insulated gate bipolar transistor provided in this embodiment, a manufacturing process is simple, and the insulated gate bipolar transistor is manufactured into a vertical structure, which not only helps to reduce a leakage current of an insulated gate bipolar transistor, improving reliability of an insulated gate bipolar transistor, but also solves a problem of an insufficient withstand voltage of a lateral insulated gate bipolar transistor, improving user experience.

As shown in FIG. 10, the embodiments of the present disclosure provide an electronic apparatus, including a processor 111, a communication interface 112, a memory 113 and a communication bus 114, and the processor 111, the communication interface 112 and the memory 113 communicate with each other via the communication bus 114.

The memory is set to store a computer program.

In an embodiment of the present disclosure, the processor 111 is set to implement the steps of the method for manufacturing the insulated gate bipolar transistor according to any of the above-mentioned method embodiments, when executing the computer program stored in the memory 113.

The embodiments of the present disclosure further provide a non-transitory computer-readable storage medium, on which a computer program is stored, and when the computer program is executed by a processor, the steps of the method for manufacturing the insulated gate bipolar transistor according to any of the above-mentioned method embodiments are implemented.

It should be noted that, in this paper, relational terms such as “first” and “second” and the like are merely used to distinguish an entity or operation from another entity or operation, and do not necessarily require or imply that there is any such actual relationship or order between these entities or operations. Moreover, a term “comprising”, “containing” or any other variation thereof is intended to encompass non-exclusive inclusion, so that a process, a method, a product or an apparatus including a series of elements not only includes those elements, but also includes other elements not explicitly listed or elements inherent to such process, method, product or apparatus. Without further restrictions, an element defined by a phrase “including a . . . ” does not exclude an existence of other identical elements in the process, method, product or apparatus including the element.

The above are merely specific embodiments of the present disclosure, so that a person skilled in the art can understand or realize the present disclosure. Various modifications to these embodiments may be obvious to a person skilled in the art, and general principles defined herein may be implemented in other embodiments without departing from the spirit or scope of the present disclosure. Therefore, the present disclosure is not be limited to the embodiments shown herein, but rather to the widest scope consistent with the principles and novel features applied herein.

What is claimed is:

1. A method for manufacturing an insulated gate bipolar transistor, comprising:
providing a substrate, and sequentially disposing an oxide layer and an epitaxial layer on the substrate, the epitaxial layer comprising a first epitaxial layer, a second epitaxial layer and a third epitaxial layer that are sequentially disposed;
disposing a trench at a side, away from the oxide layer, of the third epitaxial layer, and disposing a polysilicon gate in the trench;
forming, by injecting a dopant with a first charge type into the side, away from the oxide layer, of the third epitaxial layer, a body region disposed at two sides of the polysilicon gate;
forming, by injecting a dopant with a second charge type into a side, away from the epitaxial layer, of the body region, an emitting region disposed at two side of the polysilicon gate;
disposing a first metal layer covering the polysilicon gate, the emitting region and the body region;
removing the substrate, and etching the oxide layer and the first epitaxial layer, to dispose through holes spaced apart from each other on the oxide layer and the first epitaxial layer, respectively; and
disposing a second metal layer at a side, away from the epitaxial layer, of the oxide layer, the second metal layer being in contact with the second epitaxial layer through the through holes on the oxide layer and the first epitaxial layer.

2. The method according to claim 1, wherein the disposing a trench at a side, away from the oxide layer, of the third epitaxial layer, and disposing a polysilicon gate in the trench comprises:
disposing an initial oxide layer on the third epitaxial layer, and coating glue on the initial oxide layer;
etching the initial oxide layer after the initial oxide layer coated with the glue is exposed and developed;
etching the third epitaxial layer after the initial oxide layer is etched, to form the trench on the third epitaxial layer;
removing the initial oxide layer, and growing a gate oxide layer in the trench, to obtain the gate oxide layer; and
disposing polysilicon on the gate oxide layer, to form the polysilicon gate.

3. The method according to claim 1, wherein before the disposing a first metal layer covering the polysilicon gate, the emitting region and the body region, the method further comprises:
depositing a dielectric oxide layer on the polysilicon gate and the emitting region; and
etching the dielectric oxide layer, to form a dielectric layer covering the polysilicon gate and a portion of the emitting region.

4. The method according to claim 3, wherein the disposing a first metal layer covering the polysilicon gate, the emitting region and the body region comprises:
depositing a metal layer on the dielectric layer, the emitting region and the body region;
coating glue on the metal layer, and then performing exposure and development on the metal layer coated with the glue; and
etching the metal layer, to form the first metal layer.

5. The method according to claim 1, wherein the disposing a second metal layer at a side, away from the epitaxial layer, of the oxide layer comprises:
depositing a metal layer on the oxide layer, coating glue on the metal layer, and then performing exposure and development on the metal layer coated with the glue; and
etching the metal layer, to form the second metal layer, so that the second metal layer is in contact with the second epitaxial layer through the through holes on the oxide layer and the first epitaxial layer.

6. The method according to claim 1, wherein the dopant with the first charge type and the dopant with the second charge type are dopants with different charge types.

7. The method according to claim 1, wherein the dopant with the first charge type is a B-ion dopant, and the dopant with the second charge type is an As-ion dopant.

8. The method according to claim 1, wherein a material of the substrate is silicon.

9. The method according to claim 1, wherein positions of the through holes on the oxide layer correspond to positions of the through holes on the first epitaxial layer, respectively, and a through hole on the oxide layer and a through hole on the first epitaxial layer of which position corresponds to a position of the through hole on the oxide layer are interconnected with each other.

10. The method according to claim 1, wherein all regions, except for a region where the polysilicon gate is located, of the third epitaxial layer are covered by the body region, and the emitting region is embedded in the body region.

11. The method according to claim 1, wherein the insulated gate bipolar transistor is manufactured into a vertical structure.

12. An insulated gate bipolar transistor, comprising:
an oxide layer disposed with through holes;
an epitaxial layer disposed at a side of the oxide layer, the epitaxial layer comprising a first epitaxial layer, a second epitaxial layer and a third epitaxial layer that are sequentially disposed, and the first epitaxial layer being disposed with through holes;
a trench disposed at a side, away from the oxide layer, of the third epitaxial layer, a polysilicon gate being disposed in the trench;
a body region disposed at the side, away from the oxide layer, of the third epitaxial layer and further disposed at two sides of the polysilicon gate;
an emitting region disposed at a side, away from the epitaxial layer, of the body region and further disposed at two sides of the polysilicon gate;
a first metal layer disposed at sides, away from the epitaxial layer, of the body region and the emitting region; and
a second metal layer disposed at a side, away from the epitaxial layer, of the oxide layer, the second metal layer being in contact with the second epitaxial layer through the through holes on the oxide layer and the first epitaxial layer.

13. An electronic apparatus, comprising a processor, a communication interface, a memory and a communication bus, wherein the processor, the communication interface and the memory communicate with each other via the communication bus;
the memory is set to store a computer program; and
when executing the computer program stored in the memory, the processor is set to implement the following steps of a method for manufacturing an insulated gate bipolar transistor:
providing a substrate, and sequentially disposing an oxide layer and an epitaxial layer on the substrate, the epitaxial layer comprising a first epitaxial layer, a second epitaxial layer and a third epitaxial layer that are sequentially disposed;
disposing a trench at a side, away from the oxide layer, of the third epitaxial layer, and disposing a polysilicon gate in the trench;
forming, by injecting a dopant with a first charge type into the side, away from the oxide layer, of the third epitaxial layer, a body region disposed at two sides of the polysilicon gate;
forming, by injecting a dopant with a second charge type into a side, away from the epitaxial layer, of the body region, an emitting region disposed at two side of the polysilicon gate;
disposing a first metal layer covering the polysilicon gate, the emitting region and the body region;
removing the substrate, and etching the oxide layer and the first epitaxial layer, to dispose through holes spaced apart from each other on the oxide layer and the first epitaxial layer, respectively; and
disposing a second metal layer at a side, away from the epitaxial layer, of the oxide layer, the second metal layer being in contact with the second epitaxial layer through the through holes on the oxide layer and the first epitaxial layer.

14. The electronic apparatus according to claim 13, wherein the disposing a trench at a side, away from the oxide layer, of the third epitaxial layer, and disposing a polysilicon gate in the trench comprises:
disposing an initial oxide layer on the third epitaxial layer, and coating glue on the initial oxide layer;
etching the initial oxide layer after the initial oxide layer coated with the glue is exposed and developed;
etching the third epitaxial layer after the initial oxide layer is etched, to form the trench on the third epitaxial layer;
removing the initial oxide layer, and growing a gate oxide layer in the trench, to obtain the gate oxide layer; and
disposing polysilicon on the gate oxide layer, to form the polysilicon gate.

15. The electronic apparatus according to claim 13, wherein before the disposing a first metal layer covering the polysilicon gate, the emitting region and the body region, the processor is further set to implement the following steps of the method for manufacturing the insulated gate bipolar transistor:
depositing a dielectric oxide layer on the polysilicon gate and the emitting region; and
etching the dielectric oxide layer, to form a dielectric layer covering the polysilicon gate and a portion of the emitting region.

16. The electronic apparatus according to claim 15, wherein the disposing a first metal layer covering the polysilicon gate, the emitting region and the body region comprises:
depositing a metal layer on the dielectric layer, the emitting region and the body region;
coating glue on the metal layer, and then performing exposure and development on the metal layer coated with the glue; and
etching the metal layer, to form the first metal layer.

17. The electronic apparatus according to claim 13, wherein the disposing a second metal layer at a side, away from the epitaxial layer, of the oxide layer comprises:
depositing a metal layer on the oxide layer, coating glue on the metal layer, and then performing exposure and development on the metal layer coated with the glue; and
etching the metal layer, to form the second metal layer, so that the second metal layer is in contact with the second epitaxial layer through the through holes on the oxide layer and the first epitaxial layer.

18. The electronic apparatus according to claim 13, wherein the dopant with the first charge type and the dopant with the second charge type are dopants with different charge types; and the dopant with the first charge type is a B-ion dopant, and the dopant with the second charge type is an As-ion dopant.

19. The electronic apparatus according to claim 13, wherein a material of the substrate is silicon.

20. A non-transitory computer-readable storage medium, on which a computer program is stored, wherein when the computer program is executed by a processor, the steps of the method for manufacturing the insulated gate bipolar transistor according to claim 1 are implemented.
